(19) United States
(12) Patent Application Publication
(10) Pub. No.: US 2010/0202211 A1
(43) Pub. Date: Aug. 12, 2010

(54) NONVOLATILE MEMORY DEVICE AND METHOD FOR PROGRAMMING THE SAME

(75) Inventors: Kitae Park, Seongnam-si (KR); Youngsun Song, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/686,058

(22) Filed: Jan. 12, 2010

(30) Foreign Application Priority Data
Feb. 9, 2009 (KR) 1020090010221

(51) Int. Cl. G11C 16/04

(52) U.S. Cl. 365/185.19; 365/185.18

(57) ABSTRACT

Provided are a nonvolatile memory device and a method for programming the same. The method for programming the nonvolatile memory device includes programming at least one memory cell of the nonvolatile memory device by repeating program loops. A first self-boosting method is applied to at least one of the program loops and a second self-boosting method, different from the first self-boosting method, is applied to at least one other of the program loops.

### CROSS-REFERENCE TO RELATED APPLICATION

A claim of priority is made under 35 U.S.C. §119 to Korean Patent Application No. 10-2009-0010221, filed on Feb. 9, 2009, in the Korean Intellectual Property Office, the subject matter of which is hereby incorporated by reference.

### BACKGROUND

The present disclosure relates to nonvolatile memory devices, and more particularly, to nonvolatile memory devices and methods for programming the same.

There is a growing need for semiconductor memory devices that are electrically erasable and programmable, and that do not require refresh operations for data retention. There is also need for increases storage capacity of semiconductor memory devices. Flash memory devices provide large storage capacity without refresh operations. Also, flash memory devices retain data even when power supply is interrupted. Therefore, the flash memory devices are widely used in electronic devices (e.g., portable electronic devices) that may undergo sudden power interruption.

A flash memory device, also known as a flash Electrically Erasable Programmable Read Only Memory (EEPROM), includes a memory cell array including floating gate transistors. The memory cell array includes multiple memory blocks. Multiple bit lines are arranged in parallel in the memory blocks. Each of the memory blocks includes multiple strings (or NAND strings) corresponding respectively to the bit lines.

Each of the strings includes a string select transistor (SST), a ground select transistor (GST), and multiple floating gate transistors that are connected in series between the SST and the GST. Each of the floating gate transistors shares a source-drain terminal with an adjacent floating gate transistor.

Also, multiple word lines are arranged across each of the strings. The control gates of the floating gate transistors are connected in common to each of the word lines.

In order to program memory cells including floating gate transistors, the memory cells are first erased to have a predetermined threshold voltage (e.g., −3V). Thereafter, a high voltage (e.g., 20V) is applied to a word line, connected to a selected memory cell, for a predetermined time to program a selected memory cell. For an accurate program operation, the threshold voltage of the selected memory cell must be increased, while the threshold voltages of unselected memory cells must be maintained without change.

However, when a program voltage is applied to a selected word line, the program voltage is applied not only to the selected memory cell, but also to unselected memory cells connected to the selected word line. Thus, the unselected memory cells connected to the selected word line may become programmed. This accidental programming of the unselected memory cells connected to the selected word line is called program disturbance.

### SUMMARY OF THE INVENTIVE CONCEPT

Embodiments of the inventive concept provide nonvolatile memory devices and methods for programming the same, which reduce program disturbance, thereby enabling increased reliability and rapid program operation.

Embodiments of the inventive concept provide a nonvolatile memory device including a memory cell array having multiple memory cells and a control logic unit configured to program the memory cells. The control logic unit divides multiple program loops into at least two program loop periods, where bias conditions for self-boosting in the program loop periods are different from each other.

In various embodiments; the bias conditions for the self-boosting depend on a level of a program voltage applied to at least one memory cell of the plurality of the memory cells. Also, the conditions for the self-boosting may depend on a program loop count.

Embodiments of the inventive concept provide a method for programming the nonvolatile memory device. The method includes programming at least one memory cell of the nonvolatile memory device by repeating program loops. A first self-boosting method is applied to at least one of the program loops and a second self-boosting method, different from the first self-boosting method, is applied to at least one other of the program loops.

In various embodiments, the first self-boosting method and the second self-boosting method may be applied selectively depending on whether the program voltage is higher than a reference voltage. The reference voltage may be variable.

In various embodiments, the first self-boosting method and the second self-boosting method may be applied selectively depending on whether a program loop count is greater than a reference count. The reference count may be variable.

### BRIEF DESCRIPTION OF THE DRAWINGS

The attached drawings illustrate exemplary embodiments of the inventive concept and, together with the description, serve to explain principles of the inventive concept. The embodiments of the present inventive concept will be described with reference to the attached drawings, in which:

FIG. 1 is a block diagram of a nonvolatile memory device, according to embodiments of the inventive concept;

FIG. 2 is a graph illustrating threshold voltage changes of an erased memory cell, according various self-boosting methods;

FIG. 3 is a graph illustrating program times, according to various self-boosting methods;

FIG. 4 is a flow chart illustrating a program method, according to embodiments of the inventive concept;

FIG. 5 is a diagram illustrating a program method, according to embodiments of the inventive concept;

FIG. 6 is a block diagram illustrating a structure of a memory cell array illustrated in FIG. 1;

FIG. 7 is a circuit diagram of a memory cell array illustrating application of a first self-boosting method, according to embodiments of the inventive concept;

FIG. 8 is a timing diagram illustrating bias conditions of the first self-boosting method of FIG. 7;

FIG. 9 is a circuit diagram of a memory cell array illustrating application of a second self-boosting method, according to embodiments of the inventive concept;

FIG. 10 is a timing diagram illustrating bias conditions of the second self-boosting method of FIG. 9;

FIG. 11 is a circuit diagram of a memory cell array illustrating a third self-boosting method, according to embodiments of the inventive concept;

FIG. 12 is a timing diagram illustrating bias conditions of the third self-boosting method of FIG. 11;

FIG. 13 is a graph illustrating threshold voltage changes of an erased memory cell for a program method, according to embodiments of the inventive concept;

FIG. 14 is a graph illustrating program times for a program method, according to embodiments of the inventive concept;

FIG. 15 is a block diagram of a computing system including a nonvolatile memory device, according to embodiments of the inventive concept; and

FIG. 16 is a block diagram of an SSD system including a nonvolatile memory device, according to embodiments of the inventive concept.

### DETAILED DESCRIPTION OF THE EMBODIMENTS

Various embodiments of the inventive concept will now be described more fully with reference to the accompanying drawings, in which illustrative embodiments are shown. The inventive concept, however, may be embodied in various different forms, and should not be construed as being limited only to the illustrated embodiments. Rather, these embodiments are provided as examples, to convey the inventive concept to one skilled in the art. Accordingly, known processes, elements, and techniques are not described with respect to some of the embodiments.

Reference numerals are indicated in the drawings depicting embodiments of the inventive concept. Throughout the drawings and written description, like reference numerals will be used to refer to like or similar elements.

Also, a nonvolatile memory device is used herein as an example in order to illustrate characteristics and functions of the various embodiments. However, those skilled in the art would understand and appreciate other advantages and implementations of the inventive concept based on the descriptions. The inventive concept may be embodied or applied through other embodiments. The detailed description may be amended or modified according to viewpoints and applications, without departing from the scope, technical idea and other objects of the present teachings.

Techniques have been proposed for preventing the effects of program disturbance. A program inhibition method based on a self-boosting scheme is disclosed, for example, in U.S. Pat. No. 5,677,873, entitled “Methods of Programming Flash EEPROM Integrated Circuit Memory Devices to Prevent Inadvertent Programming of Nondesignated NAND Memory Cells Therein,” and in U.S. Pat. No. 5,991,202, entitled “Method for Reducing Program Disturb During Self-Boosting in a NAND Flash Memory.”

In a program inhibition method based on a self-boosting scheme, a voltage of 0V is applied to the gate of a ground select transistor to interrupt a ground path. A voltage of 0V is applied to a selected bit line, and a power supply voltage Vcc is applied as a program inhibition voltage to an unselected bit line.

At the same time, the power supply voltage Vcc is applied to the gate of a string select transistor to charge the source of the string select transistor to a voltage of Vcc-Vth (where Vth is the threshold voltage of the string select transistor), thereby turning off (or shutting off) the string select transistor.

A program voltage Vpgm is then applied to a selected word line, and a pass voltage Vpass is applied to unselected word lines, to boost the channel voltage of a program-inhibited cell transistor. This prevents F-N tunneling between a channel and a floating gate, so that the program-inhibited cell transistor maintains the initial erase state.

A program inhibition method based on a local self-boosting scheme is disclosed, for example, in U.S. Pat. No. 5,715,194, entitled “Bias Scheme of Program Inhibit for Random Programming in a NAND Flash Memory,” and in U.S. Pat. No. 6,061,270, entitled “Method for Programming a Non-Volatile Memory Device with Program Disturb Control.”

In a program inhibition method based on a local self-boosting scheme, a voltage of 0V is applied to two unselected word lines adjacent to a selected word line. Also, after a pass voltage Vpass (e.g., 10V) is applied to other unselected word lines, a program voltage Vpgm is applied to the selected word line.

Under such bias conditions, the channel of a self-boosted cell transistor is restricted to the selected word line, and the channel boosting voltage of a program-inhibited cell transistor is increased in comparison with a program inhibition method based on a self-boosting scheme. Therefore, F-N tunneling does not occur between the channel and the floating gate of the program-inhibited cell transistor, so that the program-inhibited cell transistor maintains the initial erase state.

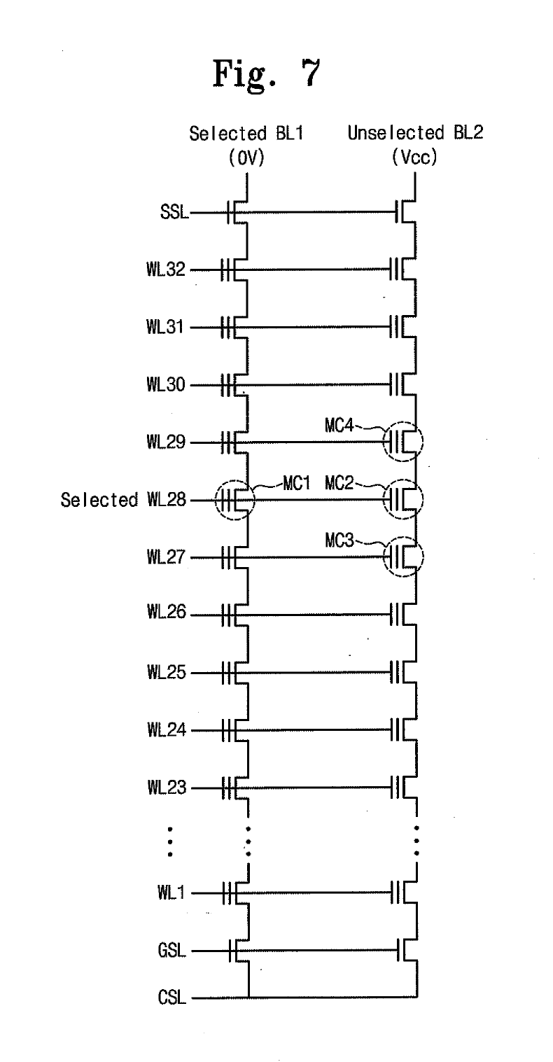

As described above, program disturbance can be suppressed by boosting channel voltage. However, various self-boosting methods have different self-boosting efficiencies and operation times, and may require undesirable tradeoffs. For example, assuming for purposes of explanation three representative self-boosting methods (examples of which are discussed below with reference to FIGS. 7-12), a first self-boosting method may have a low self-boosting efficiency, but a short operation time. Thus, although the program time is shorter, the low self-boosting efficiency increases the possibility of the occurrence of program disturbance.

In comparison, a third self-boosting method may have a high self-boosting efficiency, but a long operation time. Thus, although the high self-boosting efficiency may decrease the possibility of program disturbance, the long operation time increases the time taken for the program operation, thus degrading system performance. A second self-boosting method may have an intermediate self-boosting efficiency and an intermediate operation time, falling between the respective self-boosting efficiencies and operation times of the first and third self-boosting methods. Accordingly, the first self-boosting method is most advantageous in terms of operation time, while the third self-boosting method is most advantageous in terms of self-boosting efficiency.

In accordance with embodiments of the inventive concept, different self-boosting methods are applied selectively, according to the attendant circumstances. For example, in an embodiment, the first self-boosting method is applied during an initial program period when a low program voltage is applied, because the frequency of occurrence of program disturbance is low during the initial program period. Thus, the self-boosting operation speed is performed more quickly during the initial program period, increasing the overall program operation speed.

The third self-boosting method is applied during a latter program period when a high program voltage is applied, because the frequency of occurrence of program disturbance is high during the latter program period. Thus, the self-boosting efficiency is increased to prevent program disturbances.

However, the scope of the inventive concept is not limited to the particular order or self-boosting methods, described herein. For example, the self-boosting method may vary according to the frequency of application of a program voltage, instead of the level of a program voltage. The reason for this is that multiple program voltages are applied in an Incremental Step Pulse Programming (ISPP) method.

In a flash memory device, an ISPP method is used to accurately control distribution of threshold voltages. According to an ISPP method, the threshold voltage of a memory cell increases in direct proportion to the program voltage applied to a word line. Thus, the threshold voltage of a memory cell can be increased incrementally by increasing the program voltage, applied to a word line, stepwise with the repetition of program loops.

As is well known in the art, each program loop includes a program period and a program verity period. The program voltage increases by a predetermined increment ΔV with each repetition of the program loops. The threshold voltage of a memory cell being programmed increases in proportion to the predetermined increment ΔV. Each program period includes a self-boosting step. Thus, when the self-boosting operation time increases, the time taken for the program operation increases. Therefore, a self-boosting method is needed that provides a rapid program operation, as well as high self-boosting efficiency.

Hereinafter, a program method according to embodiments of the inventive concept will be described with reference to the accompanying drawings.

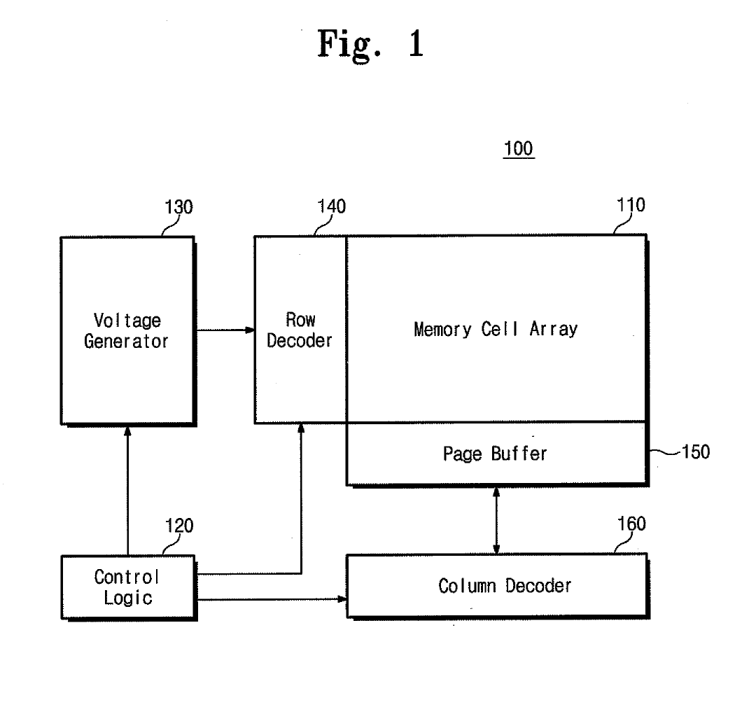

FIG. 1 is a block diagram of a nonvolatile memory device, according to embodiments of the inventive concept.

Referring to FIG. 1, a nonvolatile memory device 100 includes a memory cell array 110, a control logic circuit 120, a voltage generator 130, a row decoder 140, a page buffer 150 and a column decoder 160.

Although not illustrated in FIG. 1, the memory cell array 110 includes memory cells that are arranged in a matrix configuration of rows (or word lines) and columns (or bit lines). The memory cells may be arranged to have a NAND or NOR structure. In the NAND structure, for example, each memory cell string includes transistors that are connected in series.

The control logic circuit 120 is configured to control overall operation of the nonvolatile memory device 100. In an exemplary embodiment, the control logic circuit 120 controls a series of program-related operations. For example, the control logic circuit 120 may be a state machine storing a program sequence, although the control logic circuit 120 is not limited to this configuration. For example, the control logic circuit 120 may also be configured to control an erase operation and/or a read operation.

Under the control of the control logic circuit 120, the voltage generator 130 generates voltages to be applied to a selected word line, an unselected word line, a string select line SSL, a ground select line GSL and a common source line CSL. Also, the voltage generator 130 may generate a program voltage Vpgm, a pass voltage Vpass, a read voltage Vread and a verify read voltage Vvfy.

Under the control of the control logic circuit 120, the row decoder 140 drives a selected word line, unselected word lines, a string select line SSL, a ground select line GSL and a common source line CSL in response to a row address.

The row decoder 140 drives the various lines using the voltages generated by the voltage generator 130. For example, in a program operation, the row decoder 140 applies the program voltage Vpgm and the pass voltage Vpass to a selected word line and an unselected word line, respectively.

The page buffer 150 operates as a sense amplifier or a write driver. In a read operation, the page buffer 150 reads data from the memory cell array 110. Specifically, the page buffer 150 senses a bit line voltage, discriminates data according to the level of the bit line voltage, and stores the discriminated data therein.

In a program operation, the page buffer 150 drives bit lines at a power supply voltage Vcc or a ground voltage 0V, according to data received through the column decoder 160. For example, ground voltage 0V is applied to a bit line connected to a memory cell to be programmed, and power supply voltage (or program inhibition voltage) Vcc is applied to a bit line connected to a memory cell not to be programmed. The principle of the page buffer 150 operating as a sense amplifier or a write driver is well known to those skilled in the art, and thus additional description is not included herein.

In response to a column address, the column decoder 160 reads data latched in the page buffer 150 or transfers data to the page buffer 150. For example, in a program operation, the column decoder 160 receives data from an external device (e.g., a host) and latches the received data in the page buffer 150.

FIG. 2 is a graph illustrating threshold voltage changes of an unselected erased cell, according to three different self-boosting methods.

Referring to FIG. 2, the axis of abscissas represents the level of program voltage Vpgm, and the axis of ordinates represents the threshold voltage Vth of an unselected erased cell. In an ISPP program operation, the program voltage Vpgm may increase with each program loop, as the program loop count increases.

In the first self-boosting method, the threshold voltage of an unselected erased cell increases with increases in the program voltage. For example, referring to FIG. 2, when the program voltage is 23V, the unselected erased cell has a threshold voltage of −1V. That is, the threshold voltage of the unselected erased cell increases by 2V. Due to the increase in the threshold voltage of the unselected erased cell, an erase stage may be misinterpreted as a program state, which degrades the reliability of the nonvolatile memory device.

In comparison with the first self-boosting method, the second self-boosting method suppresses increases in the threshold voltage of the unselected erased cell. Also, in comparison with the first and second self-boosting methods, the third self-boosting method further suppresses increases in the threshold voltage of the unselected erased cell. Thus, the third self-boosting method is most advantageous for preventing program disturbance.

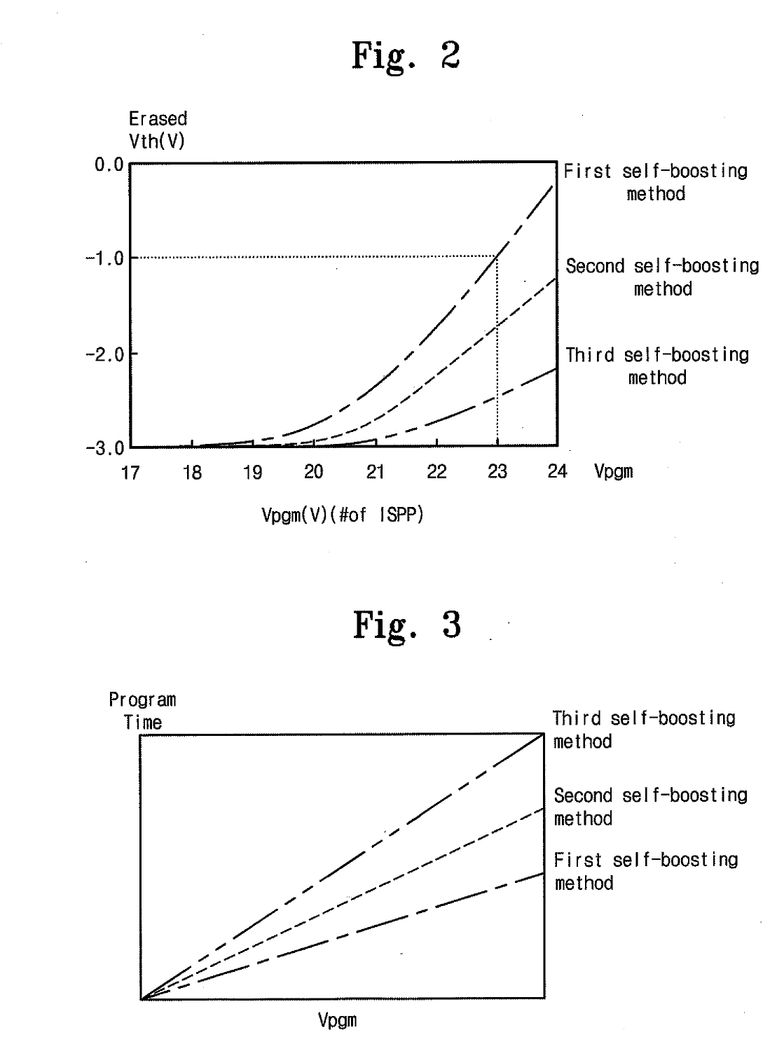

FIG. 3 is a graph illustrating program time, according to each of the self-boosting methods.

Referring to FIG. 3, the axis of abscissas represents the level of program voltage Vpgm, and the axis of ordinates represents the time taken to perform a program operation (hereinafter referred to as the program time).

In the third self-boosting method, the program time increases rapidly with increases in the program voltage. That is, the third self-boosting method has the highest slope with respect to program time increases versus program voltage increases. The reason for this is that the third self-boosting method is long in terms of the preparation period before application of the program voltage.

In comparison with the third self-boosting method, the second self-boosting method is smaller in terms of increases in the program time due to increases in the program voltage. The reason for this is that the preparation period before application of the program voltage in the second self-boosting method is much shorter than the preparation period of the third self-boosting method.

Also, in comparison with the second self-boosting method, the first self-boosting method is smaller in terms of increases in the program time. The reason for this is that the preparation period before application of the program voltage in the first self-boosting method is much shorter than the preparation period of the second self-boosting method. Thus, the first self-boosting method is most advantageous in terms of the program time.

According to various embodiments, when the program voltage reaches a reference voltage, the self-boosting method changes. For example, the first self-boosting method may be used during the initial program stage, and the second self-boosting method may be used when the program voltage reaches a first reference voltage. Also, the third self-boosting method may be used when the program voltage reaches a second reference voltage. Thus, program speed is higher during the initial program stage, while self-boosting efficiency is higher during the latter program stage. In an embodiment, the first and second reference voltages may be variable to provide benefits based on particular situations or implementations.

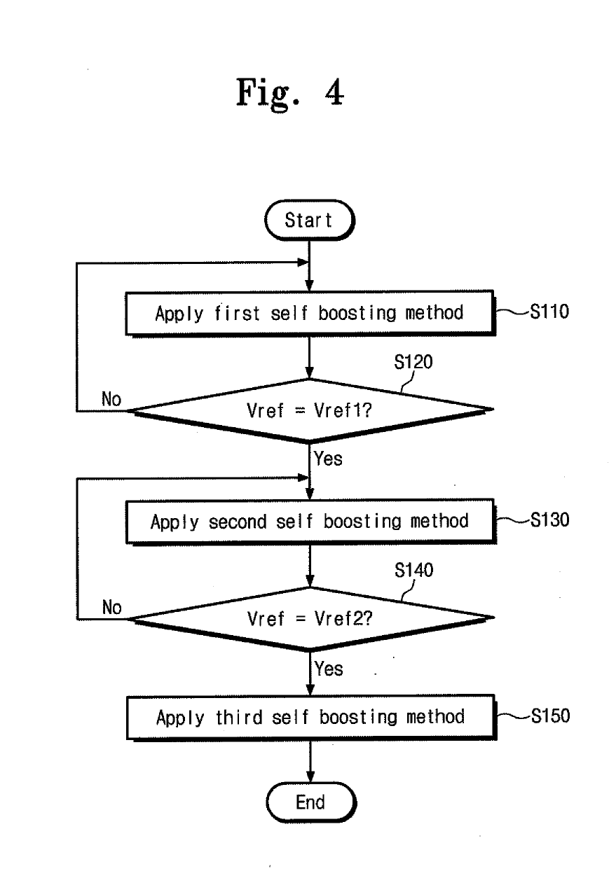

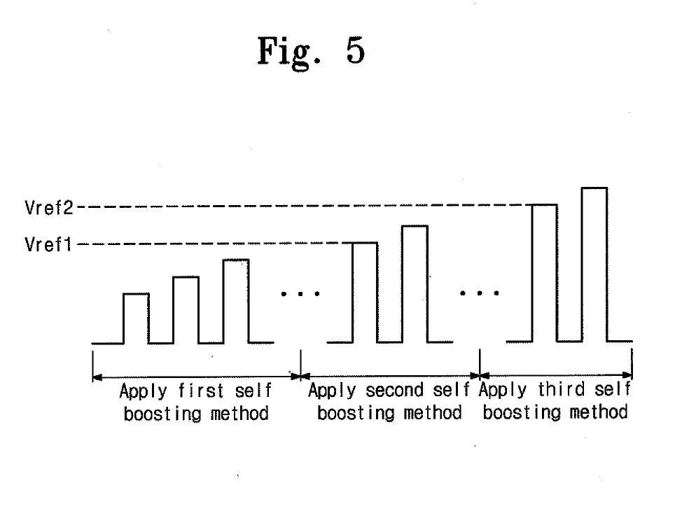

FIG. 4 is a flow chart illustrating a program method, according to various embodiments of the inventive concept.

Referring to FIG. 4, in step S110, a first self-boosting method is initially applied during a program operation. As described above, the first self-boosting method has a low boosting efficiency and a high operation speed. In step S120, the program method determines whether the program voltage Vpgm has reached a first reference voltage Vref1 during the program loops. If the program voltage Vpgm has reached the first reference voltage Vref1, the program method proceeds to step S130. If the program voltage Vpgm has not reached the first reference voltage Vref1, the program method returns to step S110 to continue to apply the first self-boosting method.

In step S130, a second self-boosting method is applied during the program operation. As described above, the second self-boosting method has an intermediate boosting efficiency and an intermediate operation speed. In step S140, the program method determines whether the program voltage Vpgm has reached a second reference voltage Vref2. If the program voltage Vpgm has reached the second reference voltage Vref2, the program method proceeds to step S150. If the program voltage Vpgm has not reached the second reference voltage Vref2, the program method returns to step S130 to continue to apply the second self-boosting method.

In step S150, a third self-boosting method is applied for a program operation. As described above, the third self-boosting method has a high boosting efficiency and a low operation speed. As described above, because the self-boosting method changes according to the current program voltage, it possible to perform a flexible program operation according to the circumstances.

Although it has been described that the self-boosting method changes depending on whether the program voltage has reached corresponding reference voltages, the scope of the inventive concept is not limited thereto. Rather, other reference criteria may be used to determine when to change self-boosting methods. For example, the self-boosting method may change depending on whether a program loop count has reached a corresponding reference count. In an embodiment, the reference count may be variable to provide benefits based on particular situations or implementations.

FIG. 5 is a diagram illustrating a program method, according to embodiments of the inventive concept.

Referring to FIG. 5, a bar graph represents levels of the program voltage. In an ISPP method, the program voltage increases with each program loop. In the depicted example, the first self-boosting method is applied to each of the program loops before the program voltage reaches the first reference voltage Vref1. The second self-boosting method is applied to each of the program loops after the program voltage reaches the first reference voltage Vref1, but before it reaches the second reference voltage Vref2. The third self-boosting method is applied to each of the program loops after the program voltage reaches the second reference voltage Vref2.

As described above, the self-boosting method changes according to the program voltage, thereby making it possible to increase the overall operation speed and boosting efficiency over that of any single self-boosting method. Also as described above, although it has been described that the self-boosting methods change depending on whether the program voltage has reached reference voltages, the scope of the inventive concept is not limited thereto. For example, the self-boosting method may change depending on whether the program loop count has reached reference counts.

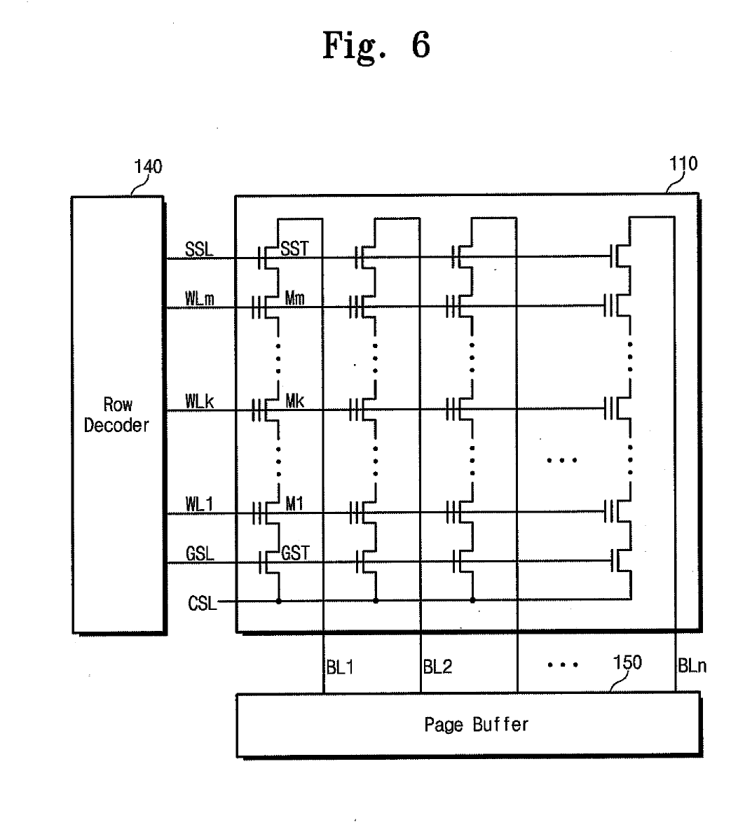

FIG. 6 is a block diagram illustrating a structure of the memory cell array 110 illustrated in FIG. 1, according to various embodiments of the inventive concept.

Referring to FIG. 6, the memory cell array 110 includes multiple word lines WL1˜WLm, multiple bit lines BL1˜BLn, and multiple memory cells M1˜Mm. The word lines WL1˜WLm of the memory cell array 110 are connected to the row decoder 140.

The row decoder 140 is connected to a string select line SSL, the word lines WL1˜WLm, and a ground select line GSL. The row decoder 140 selects one or more of the word lines in response to a row address (not illustrated).

The bit lines BL1˜BLn of the memory cell array 110 are connected to the page buffer 150. The page buffer 150 drives the bit lines BL1˜BLn. According to an exemplary embodiment, in a program operation, the page buffer 150 applies a ground voltage 0V to a selected bit line and a program inhibition voltage Vcc to an unselected bit line.

FIG. 7 is a circuit diagram illustrating application of a first self-boosting method, according to embodiments of the inventive concept.

Referring to FIG. 7, it is assumed that representative memory cell MC1 is programmed and representative memory cell MC2 is not programmed. The memory cell MC1 is connected to a selected word line WL28 and a selected bit line BL1. The unselected memory cell MC2 is connected to the selected word line WL28 and an unselected bit line BL2.

When the memory cell MC1 is programmed, the memory cell MC2 must not be programmed. In order not to program the memory cell MC2, a program inhibition voltage Vcc is applied to the unselected bit line BL2.

A local self-boosting scheme is applied according to the inventive concept. In the first self-boosting method of FIG. 7, a local voltage Vlocal (not shown) is applied to unselected word lines WL27 and WL29 adjacent to the selected word line WL28. The local voltage Vlocal is set to turn off the transistors corresponding to the adjacent unselected word lines WL27 and WL29. Accordingly, the channel of the memory cell MC2 transistor is floated, thus increasing the boosting efficiency of the channel voltage.

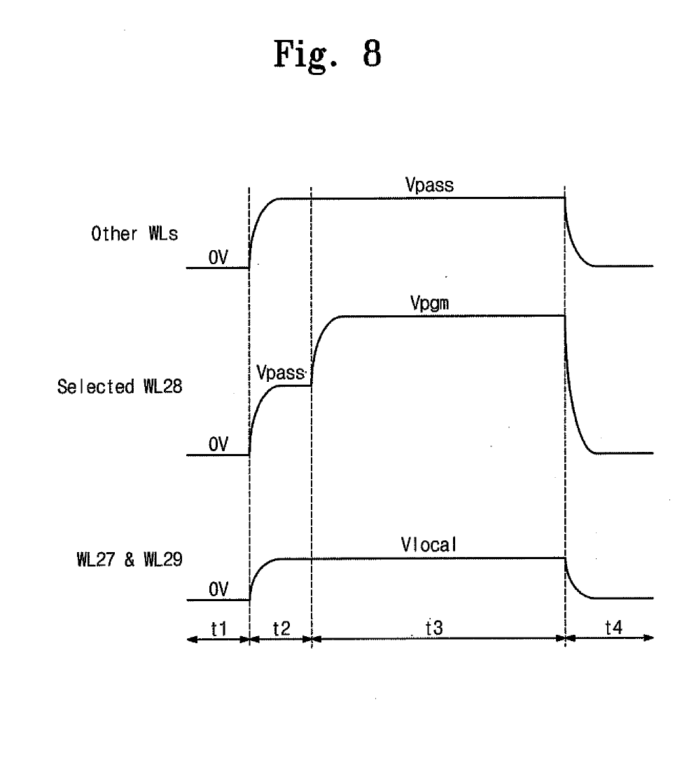

The scope of the inventive concept is not limited to the above bias conditions. For example, the unselected word lines WL27 and WL29 do not necessarily need to be adjacent to the selected world line WL28, meaning that multiple word lines may be disposed between the selected word line WL28 and each of the unselected word lines WL27 and WL29. Also, in this case, the channel is floated, thus increasing the boosting efficiency. The bias conditions according to the first self-boosting method will be described below with reference to FIG. 8.

FIG. 8 is a timing diagram illustrating bias conditions according to the first self-boosting method of FIG. 7.

Referring to FIG. 8, a program method according to the inventive concept includes steps t1 to t4. In step t1, a ground voltage 0V is applied to each of the respective word lines for initialization. In step t2, the selected word line WL28 and other word lines Other WLs (word lines other than word lines WL27-WL29) are driven by a pass voltage Vpass. By application of the pass voltage Vpass, the transistors corresponding to these word lines are turned on.

Also in step t2, a local voltage Vlocal is applied to unselected word lines WL27 and WL29 adjacent to the selected word line WL28. By application of the local voltage Vlocal, the transistors corresponding to the word lines WL27 and WL29 are turned off. Accordingly, the channel is isolated. The local voltage includes the ground voltage, and may be a suitable voltage capable of turning off the transistor.

In step t3, the selected word line WL28 is driven by a program voltage Vpgm. By application of the program voltage Vpgm, the channel voltage increases. Due to the increased channel voltage, a representative unselected memory cell MC2 of the selected word line WL28 is not programmed. In step t4, the word lines are respectively driven by the ground voltage V0 for recovery.

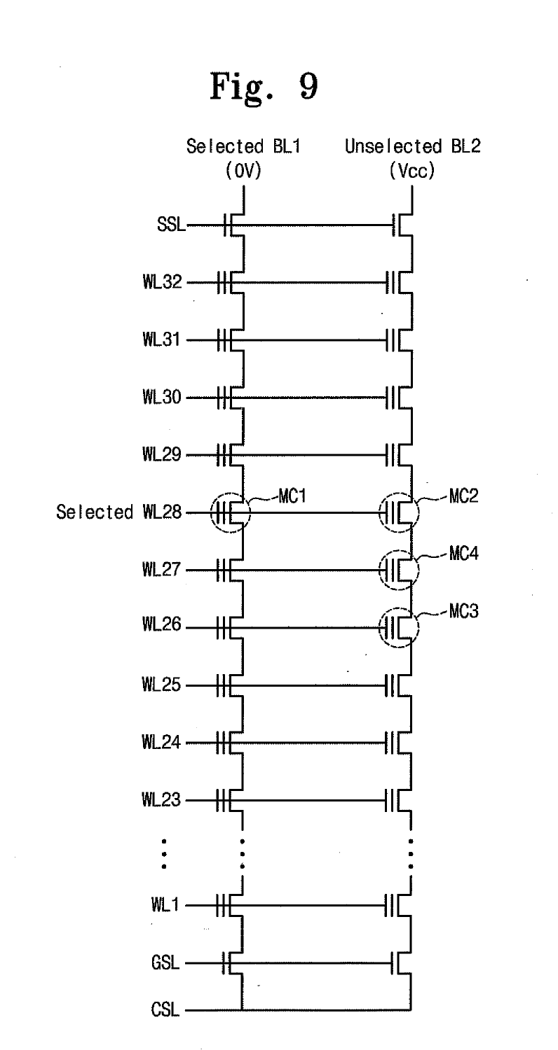

FIG. 9 is a circuit diagram illustrating application of a second self-boosting method, according to embodiments of the inventive concept.

Referring to FIG. 9, it is assumed that memory cell MC1 is programmed and memory cell MC2 is not programmed. The memory cell MC1 is connected to a selected word line WL28 and a selected bit line BL1. The memory cell MC2 is connected to the selected word line WL28 and an unselected bit line BL2.

When the memory cell MC1 is programmed, the memory cell MC2 must not be programmed. In order not to program the memory cell MC2, a program inhibition voltage Vcc is applied to the unselected bit line BL2.

A local self-boosting scheme is applied according to the inventive concept. In the second self-boosting method of FIG. 9, a ground voltage 0V (or a voltage for turning off the transistor) is aplied to an unselected word line WL26. Accordingly, the channel is isolated, thus increasing the boosting efficiency of the channel voltage.

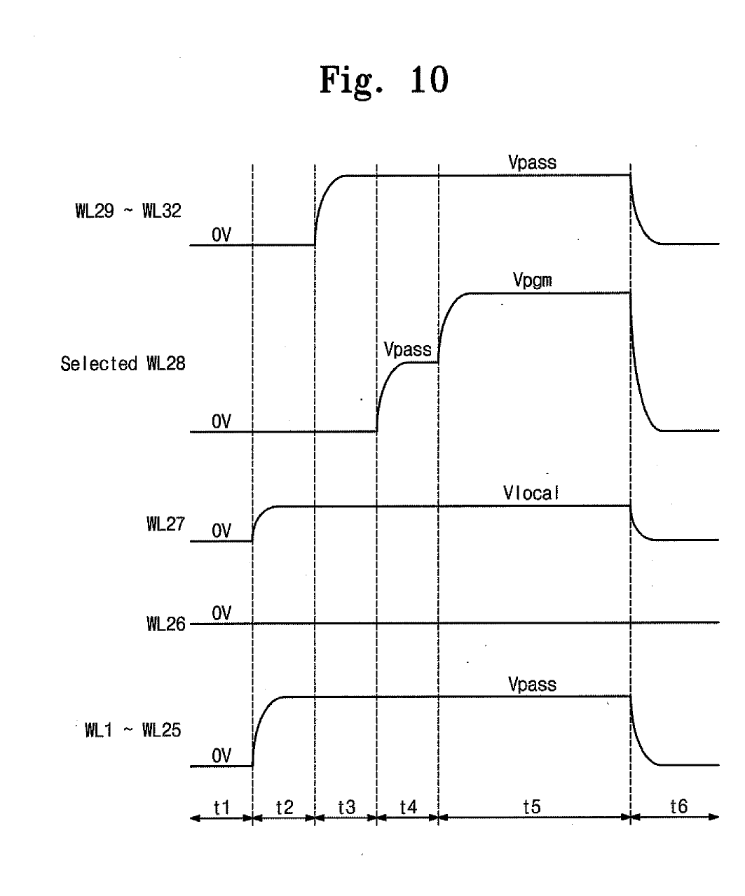

The scope of the inventive concept is not limited to the above bias conditions. For example, the unselected word line WL27 (adjacent to unselected word line WL26) does not necessarily need to be adjacent to the selected world line WL28, meaning that multiple word lines may be disposed between the selected word line WL28 and the unselected word line WL27. Also; in this case, the channel is floated, thus increasing the boosting efficiency. The bias conditions according to the second self-boosting method will be described below with reference to FIG. 10.

FIG. 10 is a timing diagram illustrating bias conditions according to the second self-boosting method of FIG. 9.

Referring to FIG. 10, a program method according to the inventive concept includes steps t1 to t6. In step t1, a ground voltage 0V is applied to each of the respective word lines for initialization.

In step t2, unselected word lines WL1˜WL25 are driven by a pass voltage Vpass. By application of the pass voltage Vpass, the transistors connected to the unselected word lines WL1˜WL25 are turned on. Also, the unselected word line WL27 adjacent to the selected word line WL28 is driven by a local voltage Vlocal. The level of the local voltage Vlocal is higher than the level of the ground voltage 0V and lower than the level of the pass voltage Vpass.

In step t3, unselected word lines WL29˜WL32 are driven by the pass voltage Vpass, and a channel voltage increases by the pass voltage Vpass. In step t4, the selected word line WL28 is driven by the pass voltage Vpass, and a channel voltage increases by the pass voltage Vpass.

In step t5, the selected word line WL28 is driven by a program voltage Vpgm, and the channel voltage increases by the program voltage. Due to the increased channel voltage, program disturbance can be prevented. In step t6, the word lines WL1˜WL32 are respectively driven by the ground voltage 0V for recovery.

In the second self-boosting method, the local voltage Vlocal and the ground voltage 0V are applied to the unselected word lines WL27 and WL26, respectively, thereby preventing a sudden change of the channel voltage. However, in the second self-boosting method, it is necessary to pre-drive the unselected word lines WL1˜WL25 by the pass voltage (step t2). Step t5 of the second self-boosting method corresponds to step t3 of the first self-boosting method. That is, in comparison with the first self-boosting method, the second self-boosting method is longer in terms of the preparation period before application of the program voltage Vpgm. Therefore, the operation speed of the nonvolatile memory device performing the second self-boosting method may be degraded as compared to the first self-boosting method.

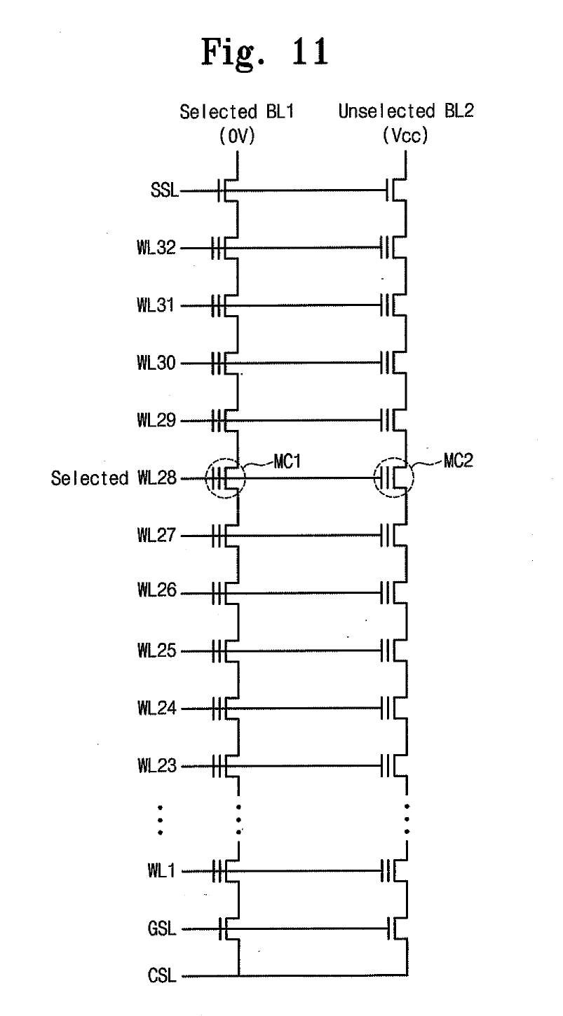

FIG. 11 is a circuit diagram illustrating application of a third self-boosting method, according embodiments of the inventive concept.

Referring to FIG. 11, it is assumed that memory cell MC1 is programmed and memory cell MC2 is not programmed. The memory cell MC1 is connected to a selected word line WL28 and a selected bit line BL1. The memory cell MC2 is connected to the selected word line WL28 and an unselected bit line BL2.

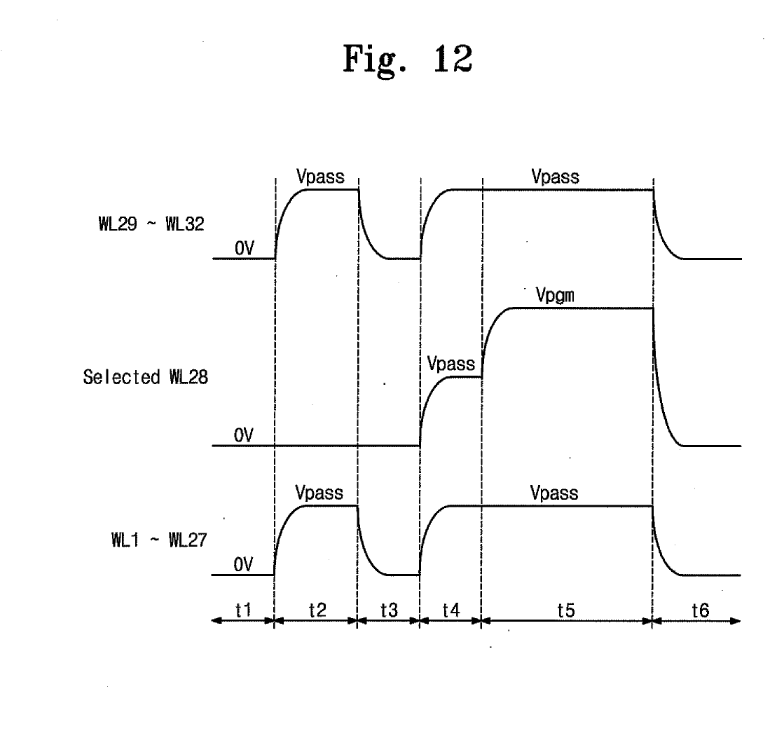

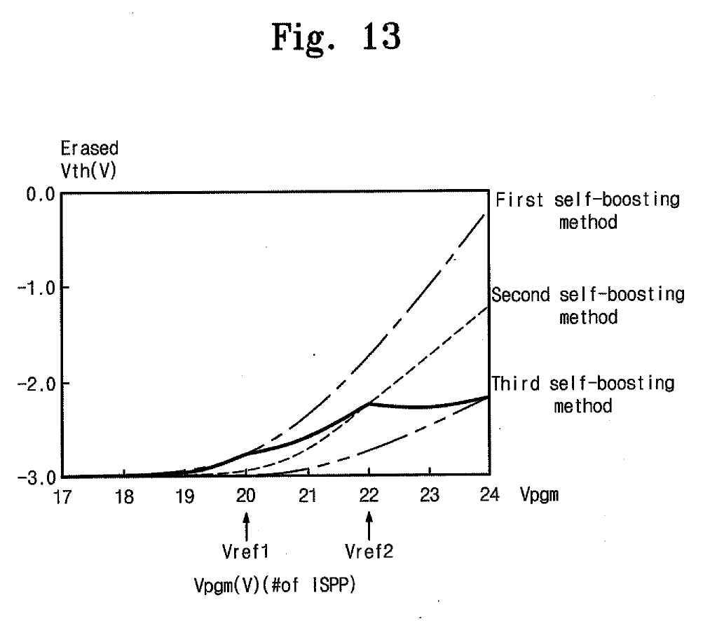

When the memory cell MC1 is programmed, the memory cell MC2 must not be programmed. In order not to program the memory cell MC2, a program inhibition voltage Vcc is applied to the unselected bit line BL2. The bias conditions according to the third self-boosting method will be described below with reference to FIG. 12.

FIG. 12 is a timing diagram illustrating bias conditions according to the third self-boosting method of FIG. 11.

Referring to FIG. 12, a program method according to the inventive concept includes steps t1 to t6. In step t1, a ground voltage 0V is applied to each of the respective word lines for initialization.

In step t2, unselected word lines WL1˜WL27 and WL29˜WL32 are driven by a pass voltage Vpass. By application of the pass voltage Vpass, the transistors connected to the unselected word lines WL1˜WL27 and WL29˜WL32 are turned on. In step t3, all of the word lines WL1˜WL32 are driven by the ground voltage 0V.

In step t4, all of the word lines WL1˜WL32 are driven by the pass voltage Vpass, and a channel voltage increases by the pass voltage. In step t5, the selected word line WL28 is driven by a program voltage Vpgm, and a channel voltage increases by the program voltage Vpgm. Due to the increased channel voltage, program disturbance can be prevented. In step t6, the word lines WL1˜WL32 are respectively driven by the ground voltage 0V for recovery.

In the third self-boosting method, the unselected word lines WL1˜WL27 and WL29˜WL32 are pre-driven by the pass voltage Vpass, thereby increasing the self-boosting efficiency. However, in the third self-boosting method, it is necessary to pre-drive the unselected word lines WL1˜WL27 and WL29˜WL32 by the pass voltage (step t2). Therefore, the operation speed of the nonvolatile memory device performing the third self-boosting method may be degraded as compared to the first and second self-boosting methods.

As described above, the first to third self-boosting methods may be applied in accordance with the inventive concept. In terms of operation speed, the first self-boosting method is the most advantageous and the third self-boosting method is the least. In terms of the boosting efficiency, the third self-boosting method is the most advantageous and the first self-boosting method is the least.

Although the self-boosting methods have been described with reference to FIGS. 7 to 12, the scope of the inventive concept is not limited thereto. As described above, embodiments of the inventive concept including applying different self-boosting methods according to the program voltage (or the program loop count). Thus, it will be apparent that any of a variety of self-boosting methods, which are different in terms of the self-boosting efficiency and/or the operation time, may be applied in accordance with the inventive concept.

FIG. 13 is a graph illustrating a threshold voltage change of an erased cell in a program method, according to various embodiments of the inventive concept, as compared to threshold voltage changes of each of the various self-boosting methods.

Referring to FIG. 13, the solid line indicates overall changes in threshold voltage Vth based on selective application of the first second and third self-boosting methods, using the first and second reference voltages Vref1 and Vref2, according to embodiments of the inventive concept. The first self-boosting method is applied before the program voltage Vpgm reaches the first reference voltage Vref1. At this point, program disturbance is not very problematic because the program voltage is low. Also, the first self-boosting method has a high operation speed, thus reducing the program operation time.

The second self-boosting method is applied when the program voltage Vpgm reaches the first reference voltage Vref1. The second self-boosting method has an intermediate boosting efficiency and an intermediate operation speed.

The third self-boosting method is applied when the program voltage Vpgm reaches the second reference voltage Vref2. The third self-boosting method has a high boosting efficiency, thus preventing program disturbance. As a result, the program speed increases during the initial program stage, while the self-boosting efficiency increases during the latter program stage, as indicated by the solid line.

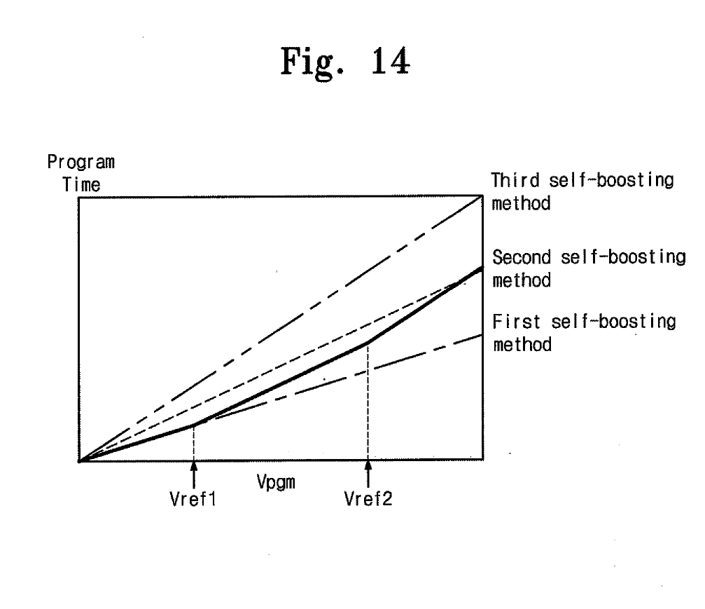

FIG. 14 is a graph illustrating a program time of a program method, according to various embodiments of the inventive concept, as compared to program times of each of the self-boosting methods.

Referring to FIG. 14, the solid line indicates overall program time based on selective application of the first, second and third self-boosting methods, using the first and second reference voltages Vref1 and Vref2, according to embodiments of the inventive concept. The first self-boosting method is applied before the program voltage Vpgm reaches the first reference voltage Vref1. The first self-boosting method has a high operation speed, thus reducing the time taken for the program operation during the initial program stage.

The second self-boosting method is applied when the program voltage Vpgm reaches the first reference voltage Vref1. The second self-boosting method has an intermediate boosting efficiency and an intermediate operation speed. That is, the second self-boosting method has a higher operation speed than the third self-boosting method. The third self-boosting method is applied when the program voltage Vpgm reaches the second reference voltage Vref2. The third self-boosting method has a high boosting efficiency, thus preventing program disturbance, but a low operation speed.

In comparison, use of only the third self-boosting method increases the boosting efficiency, but greatly reduces the program speed. Also, the use of only the first self-boosting method increases the program speed, but greatly reduces the boosting efficiency. As a result, the use of the inventive concept makes it possible to increase both the self-boosting efficiency and the program speed, overall.

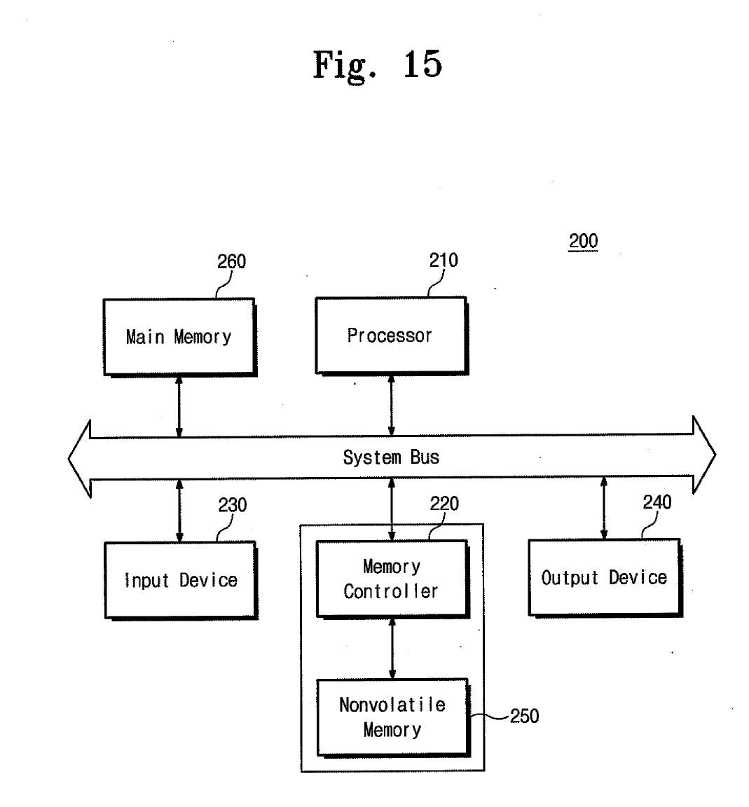

FIG. 15 is a block diagram of a computing system 200, including a nonvolatile memory device, according to various embodiments of the inventive concept.

Referring to FIG. 15, the computing system 200 includes a processor 210, a memory controller 220, input device 230 (representing one or more input devices), output device 240 (representing one or more output devices), a nonvolatile memory device 250, and a main memory device 260. In FIG. 15, a solid line denotes a system bus for transferring data and/or commands.

The memory controller 220 and the nonvolatile memory device 250 may constitute a memory card. Also, the processor 210, the input device 230, the output device 240, and the main memory device 260 may constitute a host that uses the memory card as a memory device.

The computing system 200 receives data from an external device through the input device 230 (e.g., a keyboard and/or a camera). The received data may be commands by users or may be multimedia data, such as image data form a camera. The received data is stored in the nonvolatile memory device 250 or the main memory device 260.

The process results of the processor 210 are stored in the nonvolatile memory device 250 and/or the main memory device 260. The output device 240 outputs the data stored in the nonvolatile memory device 250 or the main memory device 260. The output device 240 outputs digital data in a format sensible by humans. For example, the output device 240 may include a display or a speaker. The program method according to embodiments of the inventive concept are applied to the nonvolatile memory device 250. As the reliability and operation speed of the nonvolatile memory device 250 increase, the reliability and operation speed of the computing system 200 also increase.

The flash memory device 250 and/or the memory controller 220 may be mounted in various types of packages. Examples of packages of the flash memory device 250 and/or the memory controller 220 include Package on Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), Thin Quad Flat Pack (TQFP), System In Package (SIP), Multi Chip Package (MCP), Wafer-level Fabricated Package (WFP), and Wafer-level Processed Stack Package (WSP), for example.

Although not illustrated in FIG. 15, a power supply unit is further provided to supply the power necessary to operate the computing system 200. Also, when the computing system 200 is a mobile device, for example, the power supply unit may include a battery to supply the power necessary to operate the computing system 200.

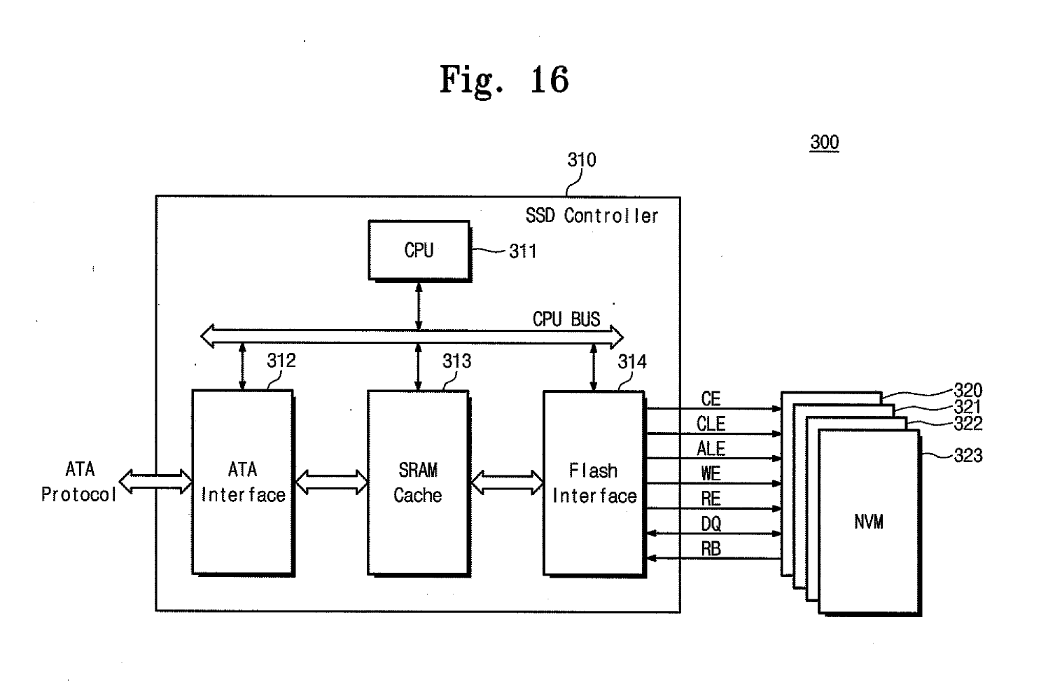

FIG. 16 is a block diagram of a solid state drive (SSD) system 300, including a nonvolatile memory device, according to embodiments of the inventive concept.

Referring to FIG. 16, the SSD system 300 includes an SSD controller 310 and nonvolatile memory (NVM) devices 320 to 323.

The nonvolatile memory device according to embodiments of the inventive concept is also applicable to SSD products. SSD products, which are expected to replace hard disk drives (HDDs), are being esteemed in the next-generation memory market. SSDs are data storage devices that store data by using memory chips such as flash memories, instead of rotatable disks used in HDDs. In comparison with HDDs operating mechanically, SSDs are high in speed, robust against external impacts, and low in power consumption.

Referring again to FIG. 16, a central processing unit (CPU) 311 receives a command from a host, and determines/controls whether to store data from the host in the nonvolatile memory device or to read data from the nonvolatile memory device and transmit the same to the host, for example.

Under the control of the CPU 311, an ATA interface 312 exchanges data with the host. The ATA interface 312 patches commands and addresses from the host and transfers the same to the CPU 311 through a CPU bus. Data, which will be received/transmitted from/to the host through the ATA interface 312, are transferred through an SRAM cache 313 without passing through the CPU bus, under the control of the CPU 311. The ATA interface 312 includes the S-ATA (serial ATA) standard and the P-ATA (parallel ATA) standard.

The SRAM cache 313 temporarily stores data exchanged between the host and the nonvolatile memory devices 320 to 323. The SRAM cache 313 is also used to store programs that will be executed by the CPU 311. The SRAM cache 313 may be regarded as a kind of buffer memory. The SRAM cache 313 may be implemented by other types of memories. A flash interface 314 exchanges data with the nonvolatile memory devices that are used as storage devices. The flash interface 314 may be configured to support NAND flash memories, One-NAND flash memories, or multi-level flash memories.

Semiconductor memory systems according to embodiments of the inventive concept may be used as portable storage devices. Thus, the semiconductor memory systems may be used as storage devices for MP3 players, digital cameras, PDAs, e-Book, and the like. The semiconductor memory systems according to embodiments of the inventive concept may also be used as storage devices for digital TVs or computers, for example.

As described above, the inventive concept increases self-boosting efficiency in a program operation, thus making it possible to prevent an unselected memory cell from being programmed, and reduces the time taken for the program operation.

The above-disclosed subject matter is to be considered illustrative and not restrictive, and the appended claims are intended to cover all such modifications, enhancements, and other embodiments, which fall within the spirit and scope of the present teachings. Thus, while the present inventive concept has been described with reference to exemplary embodiments, it will be apparent to those skilled in the art that various changes and modifications may be made without departing from the spirit and scope of the present teachings. Therefore, it should be understood that the above embodiments are not limiting, but illustrative.

What is claimed is:

1. A nonvolatile memory device comprising:
a memory cell array including a plurality of memory cells; and
a control logic unit configured to program the memory cells, the control logic unit dividing a plurality of program loops into at least two program loop periods, wherein bias conditions for self-boosting in the program loop periods are different from each other.

2. The nonvolatile memory device of claim 1, wherein the bias conditions for the self-boosting depend on a level of a program voltage applied to at least one memory cell of the plurality of the memory cells.

3. The nonvolatile memory device of claim 2, wherein the bias conditions for self-boosting are changed when the program voltage is greater than a reference voltage.

4. The nonvolatile memory device of claim 1, wherein the bias conditions for the self-boosting depend on a program loop count.

5. The nonvolatile memory device of claim 4, wherein the bias conditions for self-boosting are changed when the program loop count is greater than a reference count.

6. A method for programming a nonvolatile memory device, the method comprising:
programming at least one memory cell of the nonvolatile memory device by repeating program loops,
wherein a first self-boosting method is applied to at least one of the program loops and a second self-boosting method, different from the first self-boosting method, is applied to at least one other of the program loops.

7. The method of claim 6, wherein the first self-boosting method and the second self-boosting method are applied selectively depending on whether the program voltage is higher than a reference voltage.

8. The method of claim 7, wherein the reference voltage is variable.

9. The method of claim 6, wherein the first self-boosting method and the second self-boosting method are applied selectively depending on whether a program loop count is greater than a reference count.

10. The method of claim 9, wherein the reference count is variable.

11. The method of claim 6, wherein a program voltage applied during a program loop adopting the first self-boosting method is lower than that applied during a program loop adopting the second self-boosting method.

12. The method of claim 6, wherein the first self-boosting method is faster than the second self-boosting method.

13. The method of claim 6, wherein a program voltage is applied to a selected word line after the first and second self-boosting methods are performed.

14. The method of claim 13, wherein a pass voltage is applied to the selected word line while the first and second self-boosting methods are performed.

15. The method of claim 13, wherein the first self-boosting method comprises:
applying a local voltage to unselected word lines adjacent to opposite sides of the selected word line; and
applying a pass voltage to unselected word lines except the unselected word line to which the local voltage is applied.

16. The method of claim 15, wherein the local voltage is a voltage for turning on memory cells to which the local voltage is applied.

17. The method of claim 15, wherein the pass voltage is a voltage for turning on memory cells to which the pass voltage is applied.

18. The method of claim 13, wherein the second self-boosting method comprises:
applying a ground voltage to an unselected word line disposed in the direction of a ground selection line among unselected word lines adjacent to opposite sides of the selected word line;
applying a local voltage to unselected word lines disposed between the selected word line and the unselected word line to which the ground voltage is applied; and
applying a pass voltage to unselected word lines except the unselected word line to which the ground voltage is applied and the unselected word lines to which the local voltage is applied.

19. The method of claim 13, further comprising a third self-boosting method,
wherein the first self-boosting method, the second self-boosting method or the third self-boosting method is applied selectively depending on whether the program voltage is greater than a reference voltage.

20. The method of claim 19, wherein the third self-boosting method comprises:
applying a pass voltage to unselected word lines;
applying a ground voltage to a selected word line and the unselected word lines;
applying a pass voltage to the selected word line and the unselected word lines; and
applying the program voltage to the selected word line.
